(19) United States
(12) Patent Application Publication
(10) Pub. No.: US 2019/0339731 A1
(43) Pub. Date: Nov. 7, 2019

(54) PROTRUSION DROP STRUCTURE AND ELECTRONIC APPARATUS HAVING PROTRUSION DROP STRUCTURE

(71) Applicant: Mitsubishi Electric Corporation, Tokyo (JP)

(72) Inventors: Yusuke KAWAI, Tokyo (JP); Masumi IHARA, Tokyo (JP); Takao KUROKI, Tokyo (JP)

(73) Assignee: Mitsubishi Electric Corporation, Tokyo (JP)

(21) Appl. No.: 16/470,522

(22) PCT Filed: Jan. 24, 2017
(86) PCT No.: PCT/JP2017/002327

§ 371 Date: Jun. 17, 2019

(51) Int. Cl. G05G 1/02; H05K 7/14; H05K 5/02

(52) U.S. Cl. CPC G05G 1/02; H05K 1/181; H05K 5/0217; H05K 7/1427

(57) ABSTRACT

To provide a protrusion drop structure and others in which when a load applied to an operating button in a back direction is smaller than a predetermined load, the bending of a printed circuit board is made sufficiently small so as not to give a feeling of strangeness when a user depresses the operating button, and when a load applied to the operating button in the back direction reaches the predetermined load, a projecting height of the operating button from a surface of a casing is reduced to less than or equal to a predetermined height. The protrusion drop structure of the present invention includes a casing; an operating button capable of being depressed, the operating button having one end that projects outside the casing and having other end disposed inside the casing; a printed circuit board supported inside the casing and having a rupturing portion that is ruptured at an area facing the other end of the operating button when a first depression load or more is applied from a one-end side to an other-end side of the operating button; and a board supporting member that is fixed to the casing and supports the printed circuit board from a back side of a surface of the rupturing portion facing the other end of the operating button, the fixation of the board supporting member to the casing being released when a second depression load or more is applied to the rupturing portion from a surface side facing the other end of the operating button to the back side.

### TECHNICAL FIELD

The present invention relates to a structure for allowing a protrusion to drop by, for example, a load applied due to an external impact.

### BACKGROUND ART

In movable bodies that transport crew members and passengers which are represented by vehicles, trains, planes, etc., in order to secure the safety of the crew members and passengers, electronic apparatuses such as various types of measuring instruments and audio devices which are installed in the movable bodies need to be configured such that protrusions such as operating buttons do not harm the human body upon collision. For example, in the case of vehicles, the European regulation (ECE-R21) defines that when a static load of 378 N is applied to a protrusion such as an operating button, the maximum projecting height from a surface of a casing should be kept less than or equal to 9.5 mm.

Regarding this, there is proposed a configuration in which a slit is provided near an area of a printed circuit board facing an operating button, and by a load acting on the operating button, a predetermined load is applied to the area of the printed circuit board facing the operating button, by which the printed circuit board is ruptured at a slit portion and the printed circuit board drops on the back side, and consequently, the projecting height of the operating button is reduced to lower than a predetermined height. Furthermore, a configuration is proposed in which to further reduce the projecting height of the operating button, an opening portion is provided in an area of a casing facing the operating button, the casing supporting the printed circuit board (Patent Literature 1).

### CITATION LIST

### Patent Literature

Patent Literature 1: JP 2005-5515 A (page 2 and FIG. 2)

### SUMMARY OF INVENTION

### Technical Problem

In the above-described conventional protrusion drop structure, since a slit is provided in the printed circuit board, the stiffness of the printed circuit board is reduced. In addition, in order for the printed circuit board to sufficiently drop, an opening portion needs to be provided in the casing, and thus, the printed circuit board cannot be supported from the back side. Therefore, there is a problem that by depressing the operating button in a back direction, the printed circuit board bends to the extent that a user is given a feeling of strangeness.

The present invention is made to solve the above-described problem, and an object of the present invention is to provide a protrusion drop structure in which when a load applied to an operating button in a back direction is smaller than a predetermined load, the bending of a printed circuit board is made sufficiently small so as not to give a feeling of strangeness when a user depresses the operating button, and when a load applied to the operating button in the back direction reaches the predetermined load, a projecting height of the operating button from a surface of a casing is reduced to less than or equal to a predetermined height.

### Solution to Problem

A protrusion drop structure according to the present invention includes: a casing; an operating button capable of being depressed, the operating button having one end that projects outside the casing and having other end disposed inside the casing; a printed circuit board supported inside the casing and having a rupturing portion that is ruptured at an area facing the other end of the operating button when a first depression load or more is applied from the one end toward the other end of the operating button; and a board supporting member that is fixed to the casing and supports the printed circuit board from a back side opposite to a surface of the rupturing portion facing the other end of the operating button, the fixation of the board supporting member to the casing being released when a second depression load or more is applied to the rupturing portion from a surface side facing the other end of the operating button to the back side.

### Advantageous Effects of Invention

The protrusion drop structure configured in the above-described manner has an advantageous effect that when a load applied to the operating button in a back direction is smaller than a predetermined load, the bending of the printed circuit board is made sufficiently small so as not to give a feeling of strangeness when a user depresses the operating button, and when a load applied to the operating button in the back direction reaches the predetermined load, a projecting height of the operating button from a surface of the casing can be reduced to less than or equal to a predetermined height.

### BRIEF DESCRIPTION OF DRAWINGS

FIG. 1 is a perspective view of a protrusion drop structure of a first embodiment of the present invention.

FIG. 2 is a cross-sectional view of the protrusion drop structure of the first embodiment of the present invention taken along line A-A of FIG. 1.

FIG. 3 is a configuration diagram of a printed circuit board in the protrusion drop structure of the first embodiment of the present invention.

FIG. 4 is a cross-sectional view of the protrusion drop structure of the first embodiment of the present invention taken along line A-A of FIG. 1 (a state in which a rupturing portion is ruptured).

FIG. 5 is a cross-sectional view of the protrusion drop structure of the first embodiment of the present invention taken along line B-B of FIG. 1.

FIG. 6 is a cross-sectional view of the protrusion drop structure of the first embodiment of the present invention taken along line B-B of FIG. 1 (a state in which a board supporting member is dropped).

FIG. 7 is a diagram showing a part of a cross-section of the protrusion drop structure of the first embodiment of the present invention taken along line A-A of FIG. 1.

FIG. 8 is a cross-sectional view of a protrusion drop structure of a second embodiment of the present invention corresponding to that taken along line A-A of FIG. 1.

### DESCRIPTION OF EMBODIMENTS

Embodiments of the present invention will be described below with reference to the drawings.

### First Embodiment

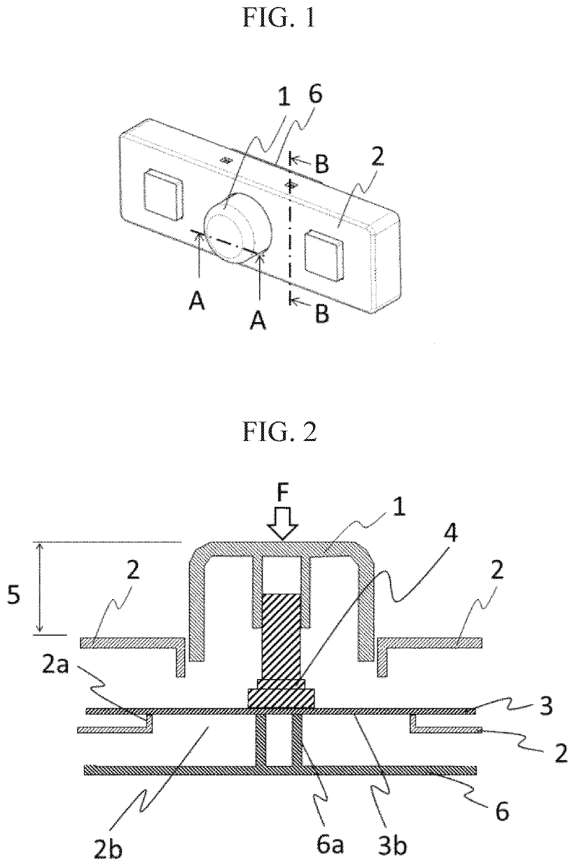

A protrusion drop structure of a first embodiment of the present invention will be described using FIGS. 1, 2, 3, 4, 5, 6, and 7.

FIG. 1 is a perspective view of the protrusion drop structure of the first embodiment of the present invention. An operating button 1 is used to operate an electronic apparatus such as a car audio device, and one end thereof projects from a casing 2 and the other end thereof is disposed inside the casing 2. Note that a target operated by the operating button 1 is not limited to an electronic apparatus.

FIG. 2 is a cross-sectional view of the protrusion drop structure of the first embodiment of the present invention taken along line A-A of FIG. 1. The operating button 1 is secured to a variable resistor 4 mounted on a printed circuit board 3, and the printed circuit board 3 determines that a depression operation has been performed, when the operating button 1 is depressed by a predetermined amount of movement or more. Likewise, the printed circuit board 3 determines that a turn operation has been performed, when the operating button 1 is turned by a predetermined amount of turn or more. Note that in order for a user to perform a turn operation on the operating button 1, an operating button projecting height 5 which is a projecting height of the operating button 1 from the casing 2 needs to be such a height that allows the user to hold the operating button 1 with a hand, and accordingly, more length is required to allow the operating button 1 to drop. The printed circuit board 3 is supported by supporting portions 2a formed by cutting and bending the casing 2. The casing 2 has a casing opening portion 2b, which is an opening, provided in an area facing the operating button 1.

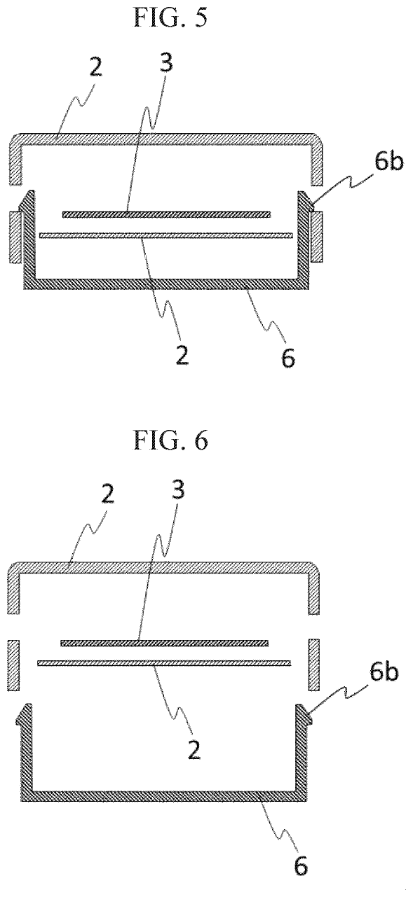

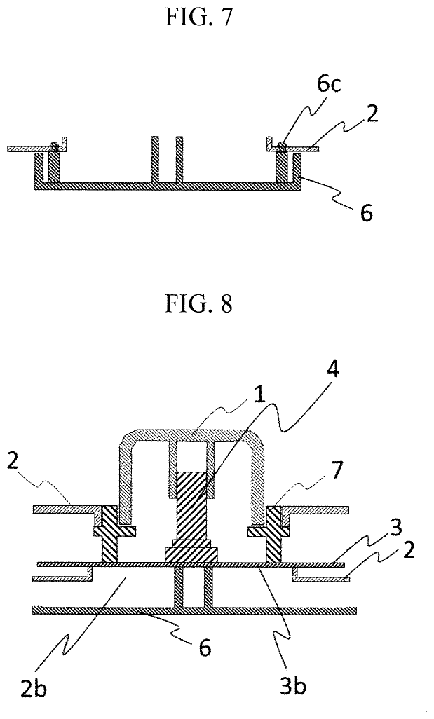

FIG. 5 is a cross-sectional view of the protrusion drop structure of the first embodiment of the present invention taken along line B-B of FIG. 1. A board supporting member 6 is fixed to the casing 2 by engaging hook-like board supporting member hook portions 6b formed on the board supporting member 6 with engagement holes made in the casing 2. Note that the board supporting member 6 may be fixed in any manner as long as its fixation to the casing 2 is released by application of a predetermined depression load, and may be fixed as shown in FIG. 7. FIG. 7 is a diagram showing a part of a cross-section of the protrusion drop structure of the first embodiment of the present invention taken along line A-A of FIG. 1. Fixation is achieved by welding board supporting member pin portions 6c which are formed in pin form on the board supporting member 6, on the casing 2. Note that fixation locations are not limited to those described above, and for example, the board supporting member pin portions 6c may be fixed, though not shown, to the top side of the casing 2 instead of the underside.

Referring back to FIG. 2, the board supporting member 6 has a board supporting member projection portion 6a which is a projection portion, and the board supporting member projection portion 6a supports the printed circuit board 3 by passing through the casing opening portion 2b and abutting on a rupturing portion 3b. Note that the board supporting member projection portion 6a may have a single or a plurality of protrusions.

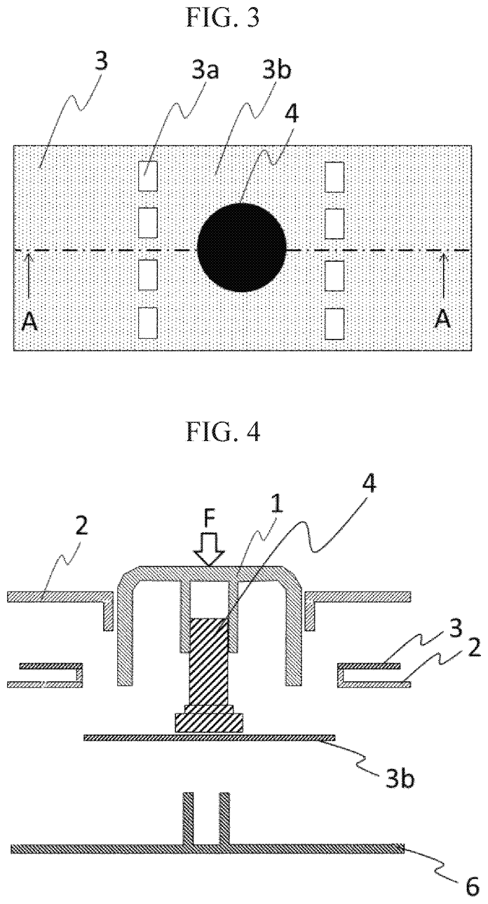

FIG. 3 is a configuration diagram of the printed circuit board in the protrusion drop structure of the first embodiment of the present invention. When the printed circuit board 3 is viewed from the operating button 1 side, the variable resistor 4 is mounted on the printed circuit board 3, and printed circuit board opening portions 3a which are openings are provided around the variable resistor 4. The rupturing portion 3b which is an area of the printed circuit board 3 enclosed by the printed circuit board opening portions 3a is ruptured when a predetermined depression load (hereinafter, referred to as a first depression load) or more is applied thereto. Note that the cross-section taken along line A-A of FIG. 1 is not present over the printed circuit board opening portions 3a.

Operation will be described in which a predetermined depression load or more is applied to the operating button 1, by which the operating button projecting height 5 becomes less than or equal to a height determined in advance (hereinafter, referred to as a predetermined height). FIG. 4 is a cross-sectional view of the protrusion drop structure of the first embodiment of the present invention taken along line A-A of FIG. 1 (a state in which the rupturing portion is ruptured). In FIG. 2, when a depression load F applied to the operating button 1 increases, the printed circuit board 3 starts to bend. By the bending of the printed circuit board 3, the depression load F is applied to the board supporting member projection portion 6a. FIG. 6 is a cross-sectional view of the protrusion drop structure of the first embodiment of the present invention taken along line B-B of FIG. 1 (a state in which the board supporting member is dropped). As described above, when a depression load is applied to the board supporting member 6 (board supporting member projection portion 6a) and the depression load F becomes greater than or equal to a predetermined depression load (hereinafter, referred to as a second depression load), the engagement between the board supporting member hook portions 6b and the casing 2 is released. Referring back to FIG. 4, by this, the support of the printed circuit board 3 by the board supporting member 6 is released and the board supporting member 6 drops off the casing 2.

Since a depression load on the printed circuit board 3 is applied to the board supporting member 6 even with a little bending of the printed circuit board 3, a feeling of strangeness is not given when the user operates the operating button 1, as long as the fixation between the board supporting member 6 and the casing 2 is not released.

Then, when the depression load F on the operating button 1 further increases and becomes greater than or equal to the first depression load, the printed circuit board 3 is ruptured, and as shown in FIG. 4, the rupturing portion 3b drops, by which the operating button projecting height 5 becomes sufficiently small and becomes less than or equal to the predetermined height.

Although in the above description the first depression load is larger than the second depression load, the first depression load and the second depression load may be equal to each other. In this case, the support of the printed circuit board 3 by the board supporting member 6 is released and the printed circuit board 3 is ruptured.

In addition, the first depression load may be set to be smaller than the second depression load by using a plastic body or an elastic body for the board supporting member 6. Note, however, that in the case of using an elastic body, such an elastic force that does not give a feeling of bending when the user operates the operating button 1 is required. In this case, the printed circuit board 3 is ruptured by application of the first depression load to the printed circuit board 3 through the operating button 1, and the support of the printed circuit board 3 by the board supporting member 6 is released by further application of the second depression load.

When the first depression load is smaller than the second depression load and a depression load greater than or equal to the first depression load and less than the second depression load is applied to the operating button 1, although the printed circuit board 3 is ruptured, the board supporting member 6 supports the printed circuit board 3, and thus, the user has difficulty recognizing the fact that an operation on the operating button 1 is in an invalid state (the user may recognize that the amount of depression is insufficient). On the other hand, when the first depression load is equal to the second depression load and a depression load greater than or equal to the first depression load is applied to the operating button 1, the printed circuit board 3 is ruptured, the support of the printed circuit board 3 by the board supporting member 6 is released, and the operating button projecting height 5 is sufficient low, and thus, the user easily recognizes that an operation on the operating button 1 is in an invalid state. When the first depression load is larger than the second depression load and a depression load greater than or equal to the second depression load and less than the first depression load is applied to the operating button 1, the support of the printed circuit board 3 by the board supporting member 6 is released, the printed circuit board 3 is not ruptured, and an operation on the operating button 1 is in a valid state, and thus, the user can recognize that an operation on the operating button 1 is in a valid state by operating the operating button 1.

From the above description, an advantageous effect can be obtained that by setting the first depression load to be greater than or equal to the second depression load, depending on a depression load applied to the operating button 1, it becomes easier for the user to recognize the valid/invalid state of the operating button 1 after the application of the depression load. In addition, setting the first depression load to be greater than or equal to the second depression load is advantageous in terms of cost and easiness of design.

As described above, the protrusion drop structure shown in the first embodiment has an advantageous effect that when a load applied to the operating button 1 in a back direction is smaller than a predetermined load, the bending of the printed circuit board 3 is made sufficiently small so as not to give a feeling of strangeness when the user depresses the operating button 1, and when a load applied to the operating button 1 in the back direction reaches the predetermined load, the operating button projecting height 5 can be reduced to less than or equal to the predetermined height.

In addition, by providing the casing opening portion 2b to allow the printed circuit board 3 (rupturing portion 3b) to drop through the casing opening portion 2b, a sufficient drop length of the operating button 1 is obtained, and as a result, the operating button projecting height 5 can be made large when an operation on the operating button 1 is in a valid state, and thus, there is an advantageous effect that ease of operation of the operating button 1 improves.

### Second Embodiment

A protrusion drop structure of a second embodiment of the present invention will be described using FIG. 8. FIG. 8 is a cross-sectional view of the protrusion drop structure of the second embodiment of the present invention corresponding to that taken along line A-A of FIG. 1. Note that in FIG. 8 the same reference signs as those of FIG. 2 indicate the same or corresponding portions. In the second embodiment, a prism 7 for guiding light is disposed around the operating button 1. The prism 7 is sandwiched between the operating button 1 and the printed circuit board 3. Here, the prism 7 may be temporarily fixed to the operating button 1 by press-fitting, thermal welding, or the like, and then sandwiched between the operating button 1 and the printed circuit board 3.

In the same manner as the protrusion drop structure of the first embodiment, when a depression load greater than or equal to a predetermined depression load is applied to the operating button 1, the support of the printed circuit board 3 by the board supporting member 6 is released, the printed circuit board 3 is ruptured at the rupturing portion 3b, the operating button 1, the variable resistor 4, the rupturing portion 3b, the board supporting member 6, and the prism 7 drop off the casing 2, and the operating button projecting height 5 is reduced to less than or equal to the predetermined height.

As described above, the protrusion drop structure shown in the second embodiment has an advantageous effect that when a load applied to the operating button 1 in the back direction is smaller than a predetermined load, the bending of the printed circuit board 3 is made sufficiently small so as not to give a feeling of strangeness when the user depresses the operating button 1, and when a load applied to the operating button 1 in the back direction reaches the predetermined load, the operating button projecting height 5 can be reduced to less than or equal to the predetermined height.

Although the above describes the application of the protrusion drop structures of the present invention to an electronic apparatus installed in a movable body, the present invention is not limited to this application, and the protrusion drop structures may be applied to electronic apparatuses used in a stationary state, such as household audio devices. In addition, the configuration of each portion may be replaced by any configuration having the same function.

### REFERENCE SIGNS LIST

1: Operating button, 2: Casing, 2a: Supporting portion, 2b: Casing opening portion, 3: Printed circuit board, 3a: Printed circuit board opening portion, 3b: Rupturing portion, 4: Variable resistor, 5: Operating button projecting height, 6: Board supporting member, 6a: Board supporting member projection portion, 6b: Board supporting member hook portion, 6c: Board supporting member pin portion, and 7: Prism.

1. A protrusion drop structure comprising:
a casing;
an operating button capable of being depressed, the operating button having one end that projects outside the casing and having other end disposed inside the casing;
a printed circuit board supported inside the casing and having a rupturing portion that is ruptured at an area facing the other end of the operating button when a first depression load or more is applied from the one end toward the other end of the operating button; and
a board supporting member that is fixed to the casing and supports the printed circuit board from a back side opposite to a surface of the rupturing portion facing the other end of the operating button, the fixation of the board supporting member to the casing being released when a second depression load or more is applied to the rupturing portion from a surface side facing the other end of the operating button to the back side.

2. The protrusion drop structure according to claim 1, wherein the first depression load is greater than or equal to the second depression load.

3. The protrusion drop structure according to claim 1, wherein the operating button has a mechanism that allows the operating button to be turned.

4. An electronic apparatus comprising a protrusion drop structure according to claim 1.
